(19) United States
(12) Patent Application Publication
(10) Pub. No.: US 2022/0093899 A1
(43) Pub. Date: Mar. 24, 2022

(54) Organic Light Emitting Diode Employing Multi-Refractive Capping Layer For Improving Light Efficiency

(71) Applicant: P&H TECH Co., Ltd, Gyeonggi-do (KR)

(72) Inventors: Seo-Yong HYUN, Gyeonggi-do (KR); Seok-Keun YOON, Gyeonggi-do (KR); Do Yeol YOON, Seoul (KR); Eunji KO, Gyeonggi-do (KR)

(73) Assignee: P&H TECH Co., Ltd, Gyeonggi-do (KR)

(21) Appl. No.: 17/470,495

(22) Filed: Sep. 9, 2021

(30) Foreign Application Priority Data
Sep. 21, 2020 (KR) 10-2020-0121295

(51) Int. Cl. H01L 51/52

(52) U.S. Cl. CPC H01L 51/5275; H01L 2251/558

(57) ABSTRACT

The present invention relates to an organic light emitting diode which complexly includes capping layers having different refractive indexes to improve light extraction efficiency, reduce a driving voltage, and improve current efficiency.

### CROSS-REFERENCE TO RELATED APPLICATIONS

This application claims priority to and the benefit of Korean Patent Application No. 10-2020-0121295 filed in the Korean Intellectual Property Office on Sep. 21, 2020, the entire contents of which are incorporated herein by reference.

### TECHNICAL FIELD

The present invention relates to an organic light emitting diode, and more particularly, to an organic light emitting diode which complexly includes capping layers having different refractive indexes to improve light extraction efficiency, reduce a driving voltage, and improve current efficiency.

### BACKGROUND ART

An organic light emitting diode is a self-emitting diode, and has a wide viewing angle, excellent contrast, fast response, and excellent luminance, driving voltage, and response speed characteristics, and has an advantage in having a possibility of polychrome.

The driving and light-emitting principle of the organic light emitting diode is as follows. When a voltage is applied between an anode and a cathode, holes injected from the anode move to a light emitting layer through a hole transport layer, and electrons injected from the cathode move to the light emitting layer through the electron transport layer, and carriers, such as the holes and the electrons, are recombined in the light emitting layer region to generate exiton. Light is generated while the exitons change from an excited state to a ground state.

Light efficiency of the organic light emitting diode may be typically divided into internal quantum efficiency and external quantum efficiency, and the internal quantum efficiency is related to how efficiently exhorts are generated and light conversion is performed in the organic layers, such as the hole transport layer, the light emitting layer, and the electron transport layer, interposed between the anode and the cathode, and the external quantum efficiency refers to efficiency (internal quantum efficiency×light extraction efficiency) at which light generated in the organic layer is extracted to the outside of the organic light emitting diode, and even though high light conversion efficiency is achieved in the organic layer within the diode, if the external quantum efficiency according to the light extraction efficiency (light coupling efficiency) is low, general light efficiency of the organic light emitting diode is inevitably reduced.

### SUMMARY OF THE INVENTION

Accordingly, the present invention has been made in an effect to provide an organic light emitting diode including a capping layer which is capable of further improving light extraction efficiency of the organic light emitting diode.

In order to solve the foregoing object, there is disclosed an organic light emitting diode, including: a substrate; an anode; a cathode; a multi-layer functional layer stacked between the anode and the cathode; and a capping layer stacked on a top of the cathode.

The multi-layer functional layer includes a hole injection layer, a hole transport layer, an electron blocking layer, a light emitting layer, a hole blocking layer, an electron transport layer, and an electron injection layer.

In the organic light emitting diode according to the present invention, the capping layer stacked on the top of the cathode (i) does not have light absorption in a visible light region.

(ii) The capping layer may be structurally formed in a single layer or multiple layers, and may be formed in a multi-layer structure with different refractive indexes or a single layer structure in which a plurality of materials having different refractive indexes is mixed, and accordingly, when the capping layer according to the present invention is formed of multiple layers, the capping layer may be formed of two to eight organic thin film layers having different refractive indexes, and may be preferably formed of two to four organic thin film layers.

(iii) According to an exemplary embodiment of the present invention, the capping layer stacked on a top of the cathode includes a first capping layer and a second capping layer, and the first capping layer and the second capping layer satisfy Equation 1 below.

n_{Layer1}−n_{Layer2}>|0.3| [Equation 1]

In Equation 1, n_{Layer1} is a refractive index at a wavelength of 430 nm of the first capping layer, and n_{Layer2} is a refractive index at a wavelength of 430 nm of the second capping layer.

(iv) The capping layer has a band gap of 3 to 4 eV.

(V) The capping layer absorbs UV at a wavelength less than 470 nm, and a maximum absorption range of UV absorbance is at a wavelength of 280 nm to 330 nm.

(vi) A total thickness of the capping layer is 40 to 200 nm, and preferably, 40 to 100 nm.

(vii) The first capping layer has a refractive index of 1.9 to 2.5, and the second capping layer has a refractive index of 1.3 to 1.8, and preferably, the first capping layer has a refractive index of 2.1 to 2.3, and the second capping layer has a refractive index of 1.4 to 1.6.

(viii) When the capping layer is formed in a single layer, a first material of which a refractive index is 1.9 to 2.5 and a second material of which a refractive index is 1.3 to 1.8 are mixed and included, and preferably, a first material of which a refractive index is 2.1 to 2.3 and a second material of which a refractive index is 1.4 to 1.6 are mixed and included. In this case, a ratio of each of the first material and the second material is 1 to 50%, and preferably, a ratio of each of the first material and the second material is 20 to 30%.

In the organic light emitting diode according to the present invention, the light emitting layer in the multi-layer functional layer includes a blue light emitting layer, a red light emitting layer, and a green light emitting layer, and a peak wavelength of a PL spectrum of the blue light emitting layer is 430 nm to 500 nm.

In the organic light emitting diode according to the present invention, blue, red, and green pixels are disposed in parallel on the substrate, and the capping layer is commonly provided in the blue, red, and green pixels.

In the organic light emitting diode according to the present invention, light transmittance of the cathode is 30% or more at a wavelength of 430 nm to 500 nm.

The organic light emitting diode according to the present invention is characterized in providing the capping layers having complex refractive indexes by complexly including materials having different refractive indexes in order to optimize light extraction efficiency, so that color purity is excellent, light extraction efficiency is improved, a driving voltage is further reduced, and a current efficiency is improved.

In particular, the first capping layer and the second capping layer having different refractive indexes are prepared and an upper layer having a low refractive index is stacked and a lower layer having a high refractive index is stacked, so that a driving voltage is reduced, current efficiency and power efficiency are improved, and light extraction efficiency is improved compared to the diode in the related art in which a capping layer having a high refractive index is solely stacked.

### BRIEF DESCRIPTION OF THE DRAWINGS

FIG. 1 is a cross-sectional view of an organic light emitting diode according to an exemplary embodiment of the present invention.

FIG. 2 is a cross-sectional view of an organic light emitting diode according to an exemplary embodiment of the present invention.

### DETAILED DESCRIPTION

Hereinafter, the present invention will be described in more detail.

The present invention relates to a top-emission type organic light emitting diode including: a substrate; an anode; a cathode, and a multi-layer functional layer stacked between the anode and the cathode; and a capping layer stacked on the cathode, which are sequentially provided, and has the following configurations.

In the organic light emitting diode according to the present invention, the multi-layer functional layer stacked between the anode and the cathode includes a hole injection layer, a hole transport layer, an electron blocking layer, a light emitting layer, a hole blocking layer, an electron transport layer, and an electron injection layer, and the light emitting layer includes a blue light emitting layer, a red light emitting layer, and a green light emitting layer.

In the organic light emitting diode according to the present invention, the blue light emitting layer has a peak wavelength of a Photoluminescence (PL) spectrum, that is, a peak wavelength of 430 nm to 500 nm, at which light emitting intensity is maximum, and includes a blue light emitting layer material satisfying the wavelength.

In the organic light emitting diode according to the present invention, blue, red, and green pixels are disposed in parallel on the substrate, and a light efficiency improving layer (capping layer) is commonly provided in the blue, red, and green pixels.

In the organic light emitting diode according to the present invention, the capping layer stacked on the cathode is designed to have the following characteristics.

(i) There is no light absorption in the visible light region, that is, in the region with a wavelength of 430 nm to 500 nm.

(ii) The capping layer may be structurally formed in a single layer or multiple layers, and may be formed in a multi-layer structure with different refractive indexes or a single layer structure in which a plurality of materials having different refractive indexes is mixed, and accordingly, when the capping layer according to the present invention is formed of multiple layers, the capping layer may be formed of two to eight organic thin film layers having different refractive indexes, and may be preferably formed of two to four organic thin film layers.

(iii) According to an exemplary embodiment of the present invention, the capping layer stacked on a top of the cathode includes a first capping layer and a second capping layer, and the first capping layer and the second capping layer satisfy Equation 1 below.

n_{Layer1}−n_{Layer2}>|0.3| [Equation 1]

In Equation 1, n_{Layer1} is a refractive index at a wavelength of 430 nm of the first capping layer, and n_{Layer2} is a refractive index at a wavelength of 430 nm of the second capping layer.

(iv) The capping layer has a band gap of 3 to 4 eV.

(v) The capping layer absorbs UV at a wavelength less than 470 nm, and a maximum absorption range of UV absorbance is a wavelength of 280 nm to 330 nm.

(vi) A total thickness of the capping layer is 40 to 200 nm, and preferably, 40 to 100 nm.

(vii) The first capping layer has a refractive index of 1.9 to 2.5, and the second capping layer has a refractive index of 1.3 to 1.8, and preferably, the first capping layer has a refractive index of 2.1 to 2.3, and the second capping layer has a refractive index of 1.4 to 1.6. When the capping layer is formed by sequentially stacking the first capping layer having a high refractive index and the second capping layer having a relatively low refractive index on a top of the cathode, light extraction efficiency is improved, a driving voltage is further reduced, and current efficiency is improved, compared to a diode in the related art in which a capping layer having a high refractive index is solely stacked.

(viii) When the capping layer is formed. in a single layer, a first material of which a refractive index is 1.9 to 2.5 and a second material of which a refractive index is 1.3 to 1.8 are mixed and included, and preferably, a first material of which a refractive index is 2.1 to 2,3 and a second material of which a refractive index is 1.4 to 1.6 are mixed and included. In this case, a ratio of each of the first material and the second material is 1 to 50%, and preferably, a ratio of each of the first material and the second material is 20 to 30%.

In the organic light emitting diode according to the present invention, the cathode is designed so that light transmittance is 30% or more at a wavelength of 430 nm to 500 nm.

The organic light emitting diode according to the present invention may be manufactured by using a general manufacturing method and material of a diode, except for having the capping layer, the light emitting layer, and the cathode with the foregoing characteristic conditions.

The multi-layer functional layer provided in the organic light emitting diode according to the present invention is the multi-layer structure in which two or more organic layers are stacked, and for example, the multi-layer functional layer may have the structure including the hole injection layer, the hole transport layer, the electron blocking layer, the light emitting layer, the hole blocking layer, the electron transport layer, the electron injection layer, and the like, and the multi-layer functional layer is not limited thereto, and may also include less or more organic layers.

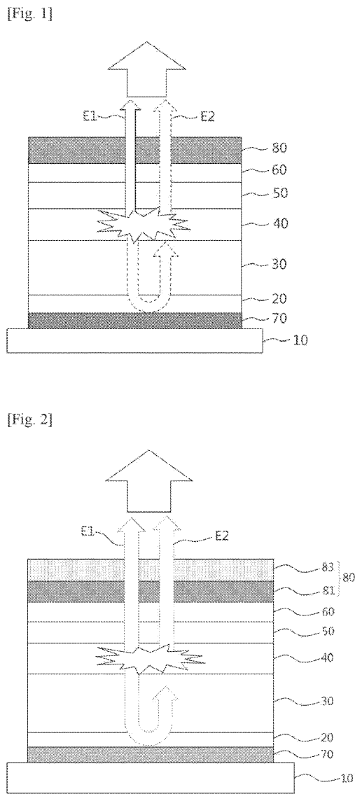

FIG. 1 is a cross-sectional view of an organic light emitting diode according to an exemplary embodiment of the present invention, and the organic light emitting diode includes a substrate 10; an anode 20 multiple functional layers (a hole injection layer and hole transport layer 30, a light emitting layer 40, an electron injection layer and electron transport layer 50); a cathode 60, and a capping layer 80, and the capping layer may be formed on a top of the cathode (top-emission type).

FIG. 1 is the case where the capping layer 80 includes a single layer, and in the capping layer 80, a first material having a refractive index of 1.9 to 2.5 and a second material having a refractive index of 1.3 to 1.8 are mixed and included.

FIG. 2 is the case where the capping layer includes a first capping layer 81 and a second capping layer 83, and structurally, the first capping layer 81 and the second capping layer 83 are sequentially stacked on the cathode 60, and the first capping layer 81 is the relatively high refractive capping layer and the second capping layer 83 is the relatively low refractive capping layer. The first capping layer 81 has a refractive index of 1.9 to 2.5, and the second capping layer 83 has a refractive index of 1.3 to 1.8. As described above, when the first capping layer 81 and the second capping layer 83 having different refractive indexes are prepared and the first capping layer having the high refractive index and the second capping layer having the relatively low refractive index are sequentially stacked on the cathode, light extraction efficiency is improved, a driving voltage is further reduced, and current efficiency is improved compared to the diode in the related art in which a capping layer having a high refractive index is solely stacked.

The capping layer 80 satisfying the characteristic condition according to the exemplary embodiment of the present invention is formed on an upper portion of the cathode 60 (top emission), the light formed in the light emitting layer 40 is emitted toward the cathode (E1), and the light formed in the light emitting layer 40 is additionally emitted toward the cathode through the reflective layer 70 formed at the side of the anode 20 (E2), and in this case, light extraction is improved while the emitted light passes through the capping layer according to the present invention, thereby improving light efficiency.

Hereinafter, an exemplary embodiment of the organic light emitting diode according to the present invention will be described in more detail.

The organic light emitting diode according to the present invention may be manufactured by forming an anode by depositing a metal, a metal oxide having conductivity, or an alloy thereof on a substrate by using a Physical Vapor Deposition (PVD) method, such as sputtering or e-beam evaporation, forming a multi-layer functional layer including a hole injection layer, a hole transport layer, a light emitting layer, an electron transport layer, and the like is formed on the anode, and then depositing a material usable as a cathode on the multi-layer functional layer, and providing a capping layer.

In addition to the foregoing method, the organic light emitting diode may also be manufactured by sequentially depositing a multi-layer functional layer and a cathode material from an anode material on a substrate. The multi-layer functional layer may have a multi-layer structure including a hole injection layer, a hole transport layer, a light emitting layer, an electron transport layer, and the like. Further, the multi-layer functional layer may be manufactured in a smaller number of layers by a solvent process, for example, spin coating, dip coating, doctor blading, screen printing, inkjet printing, or a thermal transfer method, not the deposition method, by using various polymer materials.

Preferably, the anode material has a high work function for easy injection of holes into the organic layers. Specific examples of anode materials suitable for use in the present invention include, but are not limited to: metals such as vanadium, chromium, copper, zinc, and gold and alloys thereof; metal oxides such as zinc oxide, indium oxide, indium thin oxide (ITO), and indium zinc oxide (IZO); combinations of metals and oxides such as ZnO:Al and SnO₂:Sb; and electrically conductive polymers such as poly(3-methylthiophene), poly[3,4-(ethylene-1,2-dioxy)thiophene] (PEDT), polypyrrole, and polyaniline.

The cathode material is preferably a material having a small work function to facilitate electron injection into the organic layer, and in the organic light emitting diode according to the present invention, in order to extract light in a front direction of the diode, light transmittance of the cathode material is preferably 30% or more at a wavelength of 430 nm to 500 nm, and is preferably transparent/translucent.

Specific examples of the cathode include metals, such as magnesium, calcium, sodium, potassium, titanium, indium, yttrium, lithium, gadolinium, aluminum, silver, tin, and lead or an alloy thereof, and a multi-layer structure material, such as LiF/Al or LiO₂/Al, but the cathode is not limited thereto, and it is preferable that the cathode has a thickness of 20 nm or less in order to achieve the foregoing light transmittance of 30% or more.

The hole injecting material is preferably a material that can receive holes injected from the anode at low voltage. The highest occupied molecular orbital (HOMO) of the hole injecting material is preferably between the work function of the anode material and the HOMO of the adjacent organic layer material. Specific examples of suitable hole injecting materials include, but are not limited to, metal porphyrin, oligothiophene, arylamine-based organic materials, hexanitrile hexaazatriphenylene, quinacridone-based organic materials, perylene-based organic materials, anthraquinone, polyaniline, and polythiophene-based conductive polymers.

The hole transport material is a material that can receive holes transported from the anode or the hole injecting layer and can transfer the holes to the light emitting layer. A material with high hole mobility is suitable as the hole transport material. Specific examples of suitable hole transport materials include arylamine-based organic materials, conductive polymers, and block copolymers consisting of conjugated and non-conjugated segments. The use of the organic electroluminescent compound according to the present invention ensures further improved low-voltage driving characteristics, high luminous efficiency, and excellent life characteristics of the device.

The light emitting material is a material that can receive and recombine holes from the hole transport layer and electrons from the electron transport layer to emit light in the visible range, A material with high quantum efficiency for fluorescence and phosphorescence is preferred as the light emitting material, Specific examples of suitable light emitting materials include, but are not limited to, 8-hydroxyquinoline aluminum complex (Alq₃), carbazole-based compounds, dimerized styryl compounds, BAlq, 10-hydroxybenzoquinoline-metal compounds, benzoxazole-based compounds, benzthiazole-based compounds, and benzimidazole-based compounds, poly(p-phenylenevinylene) (PPV)-based polymers, spiro compounds, polyfluorene, and rubrene.

However, in the blue light emitting layer in the organic light emitting diode according to the present invention, a blue light emitting layer material is designed so that a peak wavelength of the PL spectrum is 430 nm to 500 nm.

The electron transport material is a material that can receive electrons injected from the cathode and can transfer the electrons to the light emitting layer. A material with high electron mobility is suitable as the electron transport material. Specific examples of suitable electron transport materials include, hut are not limited to, 8-hydroxyquinoline Al complex (Alq₃), Alq₃ complexes, organic radical compounds, hydroxyflavone-metal complexes.

Hereinafter, in the organic light emitting diode according to the present invention, the present invention will be described in more detail based on Examples using the capping layer material satisfying the characteristic condition.

### Diode Example (Capping Layer)

In the Example according to the present invention, an anode was patterned so as to have a light emission area of 2 mm×2 mm by using an ITO glass substrate including Ag having a size of 25 mm×25 mm×0.7 mm, and then cleaned. After the patterned ITO substrate was mounted to a vacuum chamber, an organic material and a metal were deposited on the substrate at a process pressure of 1×10⁻⁶ torr or more in a following structure.

### Diode Examples 1 and 2

A light emission characteristic including light emission efficiency was measured by providing a first capping layer and a second capping layer satisfying the characteristic condition according to the present invention and manufacturing an organic light emitting diode having the following diode structure.

Ag/ITO/hole injection layer (HAT-CN, 5 nm)/hole transport layer (TAPC, 100 nm)/electron blocking layer (TCTA, 10 nm)/light emitting layer (20 nm)/electron transport layer (201:Liq, 30 nm)/LiF (1 nm)/Mg:Ag (15 nm)/first capping layer (40 nm)/second capping layer (15 nm)

HAT-CN was deposited in a thickness of 5 nm to form a hole injection layer on an ITO transparent electrode including Ag on a glass substrate, and then TAPC was deposited in a thickness of 100 nm in order to form a hole transport layer. TCTA was deposited in a thickness of 10 nm to form an electron blocking layer. Further, a host compound and a dopant compound were co-deposited on a light emission layer by using BH1 and BD1, respectively, in a thickness of 20 nm. In addition, an electron transport layer was deposited in a thickness of 30 nm and 1 nm by using [201] compound (Liq 50% doping) and LiF, respectively. Subsequently, Mg:Ag was deposited in a ratio of 1:9 in a thickness of 15 nm. Further, the organic light emitting diode was manufactured by forming a light emission improving layer (capping layer) in multiple layers, and depositing a first capping layer in a thickness of 40 nm and a second capping layer in a thickness of 15 nm.

### Diode Comparative Example 1

An organic light emitting diode for Diode Comparative Example 1 was manufactured in the same manner as that of the Example, except that Alq₃ was used as the second capping layer compound.

### Diode Comparative Example 2

An organic light emitting diode for Diode Comparative Example 2 was manufactured in the same manner as that of the Example, except that the second capping layer was not formed and only the first capping layer was deposited in a thickness of 55 nm.

### Experimental Example 1

### Light Emission Characteristics of Diode Examples 1 and 2

For the organic light emitting diodes manufactured according to the Example and the Comparative Example, a driving voltage, current efficiency, and power efficiency were measured by using a source meter (Model 237, Keithley) and a luminance meter (PR-650, Photo Research), and the result values of the driving voltage, current efficiency, power efficiency, and light extraction efficiency based on 1,000 nit are represented in Table 1 below.

TABLE 1

| | Light | | | | |
|---|---|---|---|---|---|
| | efficiency | | Light | Power | |
| | improving | Driving | emission | effi- | Light |
| | layer (first/ | voltage | efficiency | ciency | extraction |
| Division | second) | (V) | (cd/A) | (lm/W) | efficiency |
| Example 1 | Compound | 5.1 | 12.0 | 7.6 | 1.15 |
| | 1/Compound 2 | | | | |
| Example 2 | Compound | 5.1 | 12.4 | 7.7 | 1.19 |
| | 1/Compund3 | | | | |
| Comparative | Compound | 5.3 | 10.9 | 6.5 | 1.05 |
| Example 1 | l/Alq₃ | | | | |
| Comparative | Compound 1 | 5.3 | 10.4 | 6.1 | 1.00 |
| Example 2 | | | | | |

Reviewing the result represented in Table 1, it can be seen that in the case where the first capping layer and the second capping layer having the different refractive indexes are provided and the material having the low refractive index is stacked on an upper layer of the material having the high refractive index like the organic light emitting diode according to the present invention, a driving voltage is reduced, current efficiency and power efficiency are improved, and light extraction efficiency is improved, compared to a diode in the related art in which a capping layer material having a high refractive index is solely stacked.

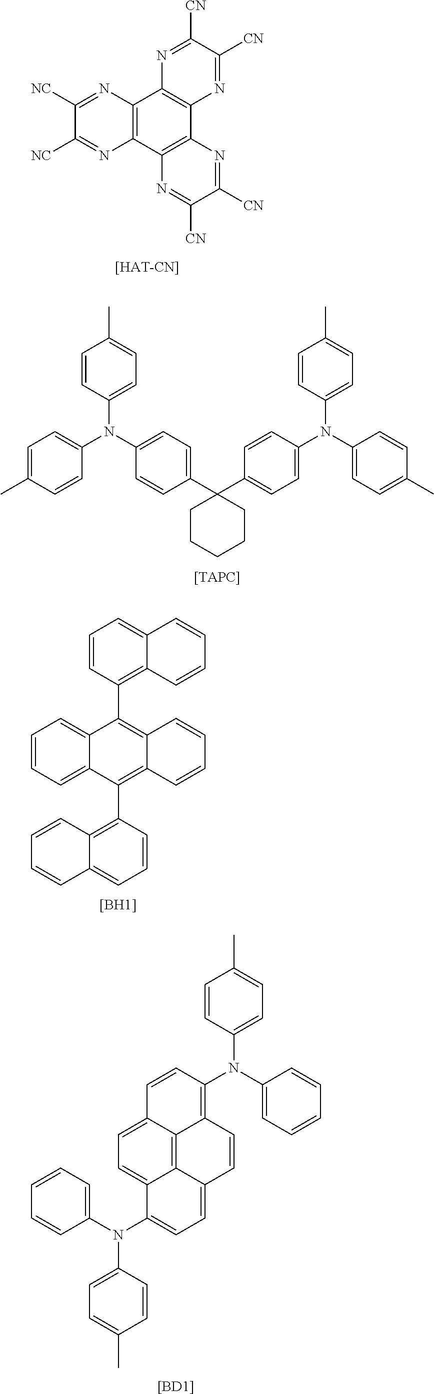

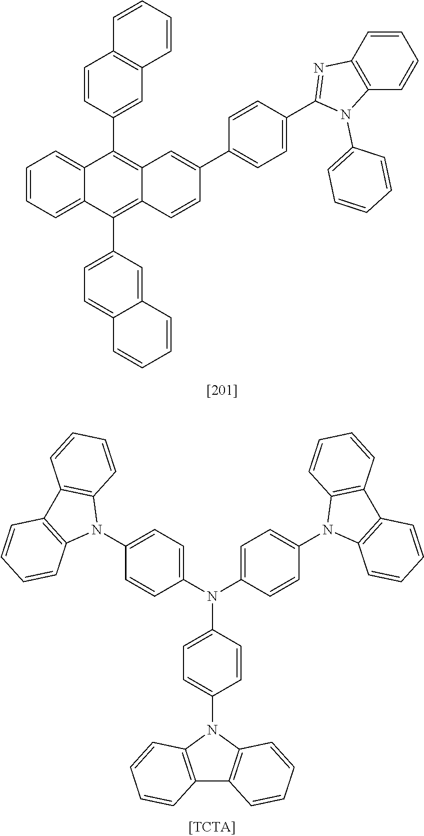 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

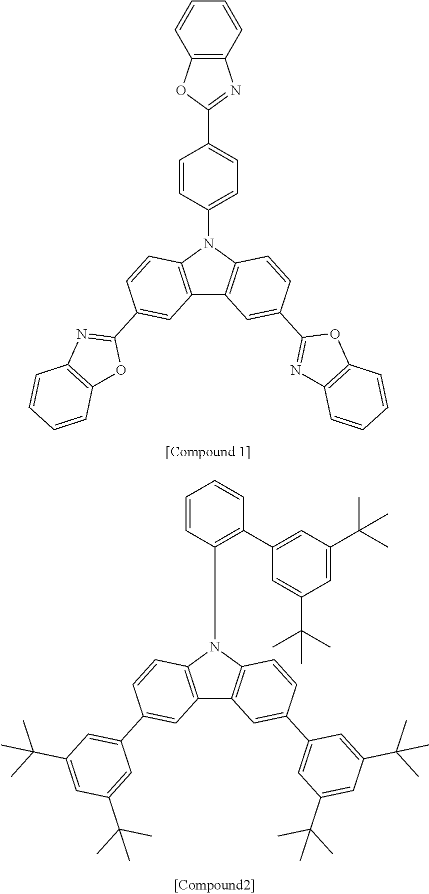 [SMILES: c1ccc2oc(-c3ccc(-n4c5ccc(-c6nc7ccccc7o6)cc5c5cc(-c6nc7ccccc7o6)ccc54)cc3)nc2c1 ; CC(C)(C)c1cc(-c2ccc3c(c2)c2cc(-c4cc(C(C)(C)C)cc(C(C)(C)C)c4)ccc2n3-c2ccccc2-c2cc(C(C)(C)C)cc(C(C)(C)C)c2)cc(C(C)(C)C)c1]

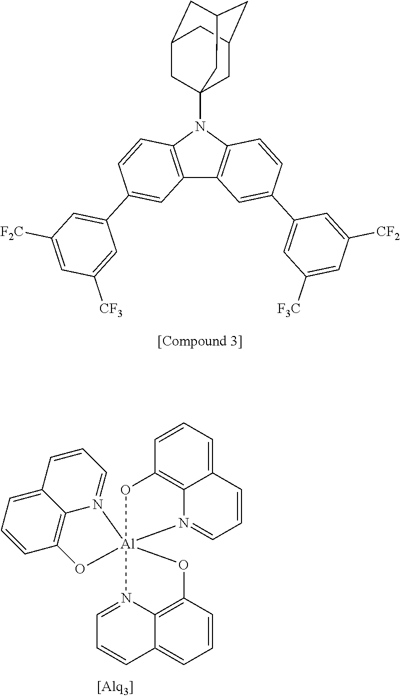

What is claimed is:

1. An organic light emitting diode, comprising:
a substrate;
an anode;
a cathode;
a multi-layer functional layer stacked between the anode and the cathode; and
a capping layer stacked on a top of the cathode,
wherein the multi-layer functional layer includes a hole injection layer, a hole transport layer, an electron blocking layer, a light emitting layer, a hole blocking layer, an electron transport layer, and an electron injection layer, and
the capping layer has no light absorption in a visible light region.

2. The organic light emitting diode of claim 1, wherein the capping layer is formed of two to eight organic thin film layers having different refractive indexes.

3. The organic light emitting diode of claim 1, wherein the capping layer includes a first capping layer and a second capping layer, and the first capping layer and the second capping layer satisfy Equation 1 below,
n_{Layer1}−n_{Layer2}>|0.3| [Equation 1]
in Equation 1, n_{Layer1} is a refractive index at a wavelength of 430 nm of the first capping layer, and n_{Layer2} is a refractive index at a wavelength of 430 nm of the second capping layer.

4. The organic light emitting diode of claim 3. wherein the first capping layer has a refractive index of 1.9 to 2.5, and the second capping layer has a refractive index of 1.3 to 1.8.

5. The organic light emitting diode of claim 1, wherein the capping layer is formed of a single layer, and includes a mixture of a first material having a refractive index of 1.9 to 2.5 and a second material having a refractive index of 1.3 to 1.8.

6. The organic light emitting diode of claim 5, wherein a ratio of each of the first material and the second material mixed in the capping layer is 1 to 50%.

7. The organic light emitting diode of claim 1, wherein a total thickness of the capping layer is 40 to 200 nm.

8. The organic light emitting diode of claim 1, wherein a peak wavelength of a PL spectrum of the light emitting layer is 430 nm to 500 nm.

9. The organic light emitting diode of claim 1, wherein the capping layer has a band gap of 3 to 4 eV,

10. The organic light emitting diode of claim 1, wherein the capping layer absorbs UV at a wavelength of less than 470 nm.

11. The organic light emitting diode of claim 1, wherein a maximum absorption range of UV absorbance of the capping layer is a wavelength of 280 to 330 nm.

12. The organic light emitting diode of claim 1, wherein light transmittance of the cathode is 30% or more at a wavelength of 430 nm to 500 nm.

13. The organic light emitting diode of claim 1, wherein the light emitting layer is a blue light emitting layer, and the multi-layer functional layer further includes a red light emitting layer and a green light emitting layer.

14. The organic light emitting diode of claim 1, wherein blue, red, and green pixels are disposed in parallel on the substrate, and the capping layer is commonly provided in the blue pixel, the red pixel, and the green pixel.
